(19) United States
(12) Patent Application Publication
(10) Pub. No.: US 2012/0285517 A1
(43) Pub. Date: Nov. 15, 2012

(54) SCHOTTKY BARRIER SOLAR CELLS WITH HIGH AND LOW WORK FUNCTION METAL CONTACTS

(75) Inventors: Joel P. de Souza, Putnam Valley, NY (US); Harold John Hovel, Katonah, NY (US); Daniel Inns, Sunnyvale, CA (US); Jeehwan Kim, Los Angeles, CA (US); Christian Lavoie, Pleasentville, NY (US); Conal Eugene Murray, Yorktown Heights, NY (US); Devendra K. Sadana, Pleasentville, NY (US); Katherine L. Saenger, Ossining, NY (US); Ghavam Shahidi, Pound Ridge, NY (US); Davood Shahrjerdi, Ossining, NY (US); Zhen Zhang, New York, NY (US)

(73) Assignee: International Business Machines Corporation, Armonk, NY (US)

(21) Appl. No.: 13/103,490

(22) Filed: May 9, 2011

(51) Int. Cl. H01L 31/108; H01L 31/18

(52) U.S. Cl. 136/255; 438/92; 257/E31.065

(57) ABSTRACT

A Schottky Barrier solar cell having at least one of a low work function region and a high work function region provided on the front or back surface of a lightly-doped absorber material, which may be produced in a variety of different geometries. The method of producing the Schottky Barrier solar cells allows for short processing times and the use of low temperatures.

### FIELD OF THE DISCLOSURE

The present disclosure relates to Schottky barrier solar cells comprising at least one of a high work function region and low work function region obtained either by use of high and low work function metals or by dopant implantation into metal silicide films.

### BACKGROUND

Solar cells offer great potential as alternative energy sources, which allow to convert sunlight directly into electricity. As the number of application areas for solar cells increases, it becomes desirable to provide new methods and materials for solar energy conversion that may be adapted to the application specific requirements.

A drawback in the past has been the initial cost of manufacturing solar cells. Thus, to make solar energy conversion economically viable, it is pertinent to implement production methods that reduce the manufacturing costs of solar cells.

Solar cells converts photons, typically from sunlight, into electricity by generating an electron/hole pair in a semiconductor through absorption of the photons. To avoid recombination of the electron/hole pair, and losing the photon energy in thermalization, the electron and the hole have to be separated, which is achieved by a built-in potential difference.

Typically, solar cells contain junction regions of one conductivity type (electron or hole), which are fabricated with diffused, ion implanted, or vapor deposited conducting regions placed onto the opposite conductivity type substrate. However, these so-called p/n junction solar cells require high temperature processing steps and prolonged manufacturing time frames.

### SUMMARY OF THE DISCLOSURE

In this disclosure, the built-in potential difference required to convert photons into electricity is created by providing a lightly-doped absorber having a front surface and a back surface; at least one of a high work function region disposed on the lightly-doped absorber; and at least one of a low work function region abutting the lightly-doped absorber and being spaced apart from the at least one high work function region; wherein the Schottky barrier solar cell comprises at least one of the high work function region or the low high work function region

Further, this disclosure is directed at a method of forming a Schottky barrier solar cell, providing a lightly-doped absorber having a front surface and a back surface, forming at least one of a p-doped region and a high work function region on the lightly-doped absorber, and forming at least one of a n-doped region and a low work function region abutting the lightly-doped absorber and being spaced apart from the at least one of p-doped region or high work function region, wherein the Schottky barrier solar cell comprises at least one of the high work function region or the low high work function region, and adjusting a potential difference at an interface between the high work function region with the lightly-doped absorber or the low high work function region and the lightly-doped absorber to be at least 0.2 volts

### BRIEF DESCRIPTION OF THE DRAWINGS

FIG. 1a shows a sideview of a lightly-doped absorber 100 having a front surface and a back surface. At the front surface, a high work function region 110 is provided. The back surface is provided with a low work function region 120. Alternatively, region 110 is a low work function region if 120 is a high work function region. Typically, the front surface is oriented perpendicularly towards the path of photons from light source 130, but the photons may also strike the front surface at an inclination. Thus, the front surface is the light-receiving surface.

Typically, the high work function region is formed as a high work function metal or a metal silicide. Moreover, the work function of the high work function region may be modified by incorporating a p-type dopant within the metal silicide and/or by further doping of the lightly-doped absorber and performing a drive-in anneal to force the dopants to migrate towards the interface of the lightly-doped absorber with the high work function metal or a metal silicide. Analogously, the low work function region is formed as a low work function metal or as a metal silicide. The work function of the low work function region may further be modified by incorporating a n-type dopant within the metal silicide, and, optionally, by further doping of the lightly-doped absorber and performing a drive-in anneal to force the dopants to migrate towards the interface of the lightly-doped absorber with low work function metal of metal silicide.

It is also possible that the Schottky barrier cell comprises a high work function metal as the high work function region and a low work function metal silicide as the low work function region, or vice versa.

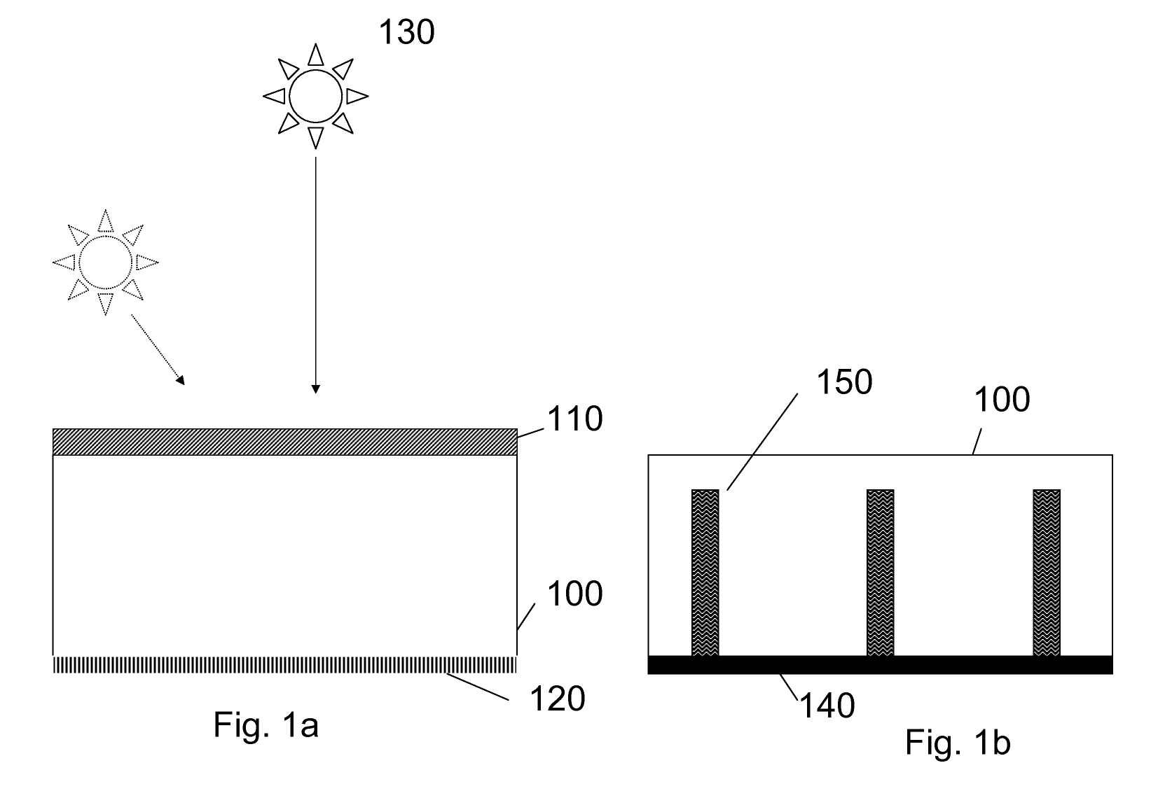

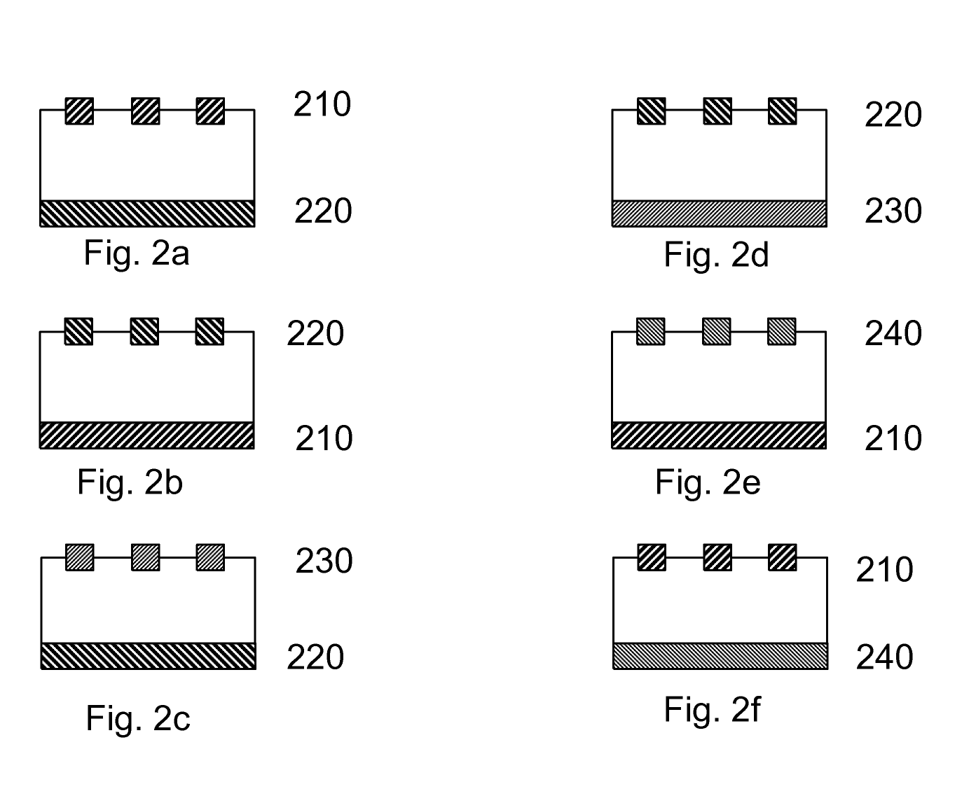

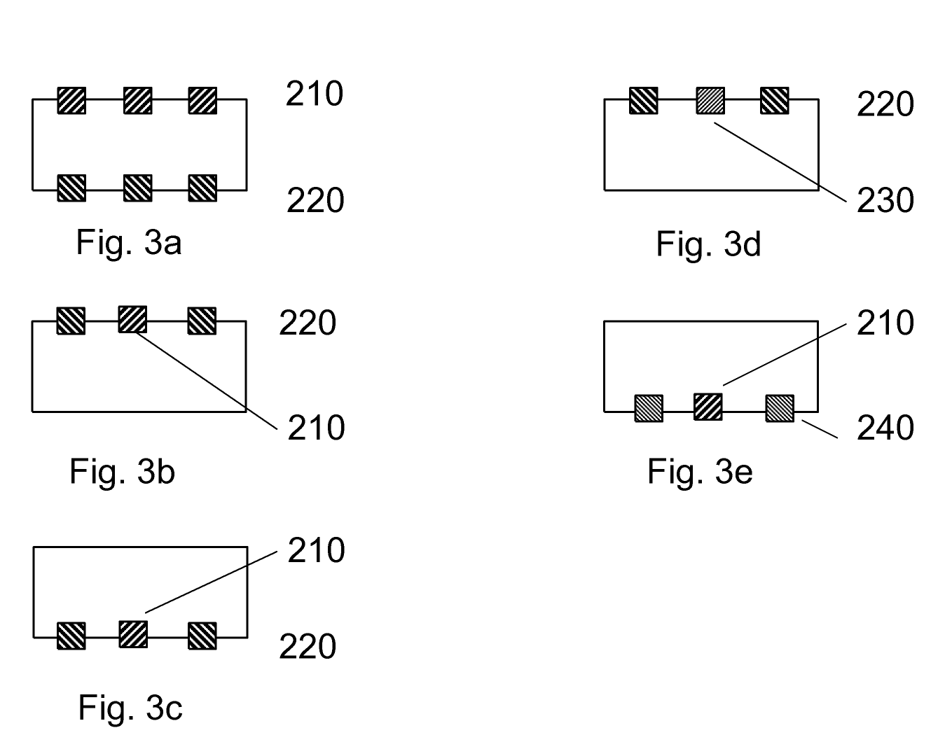

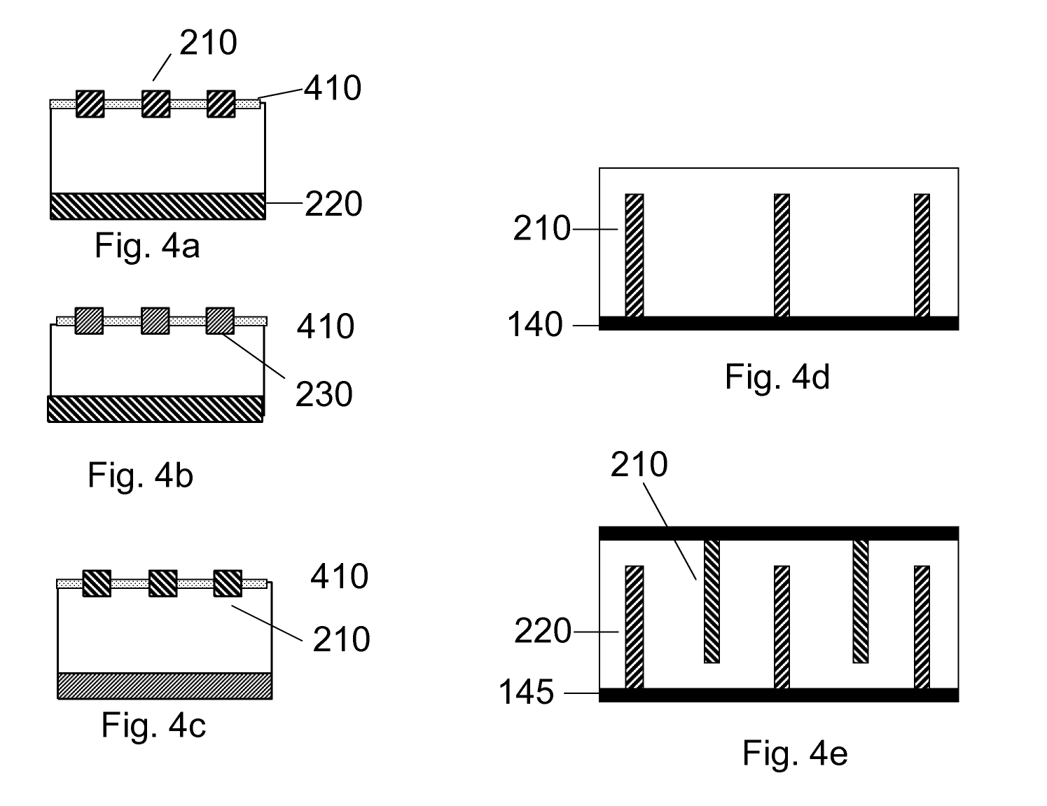

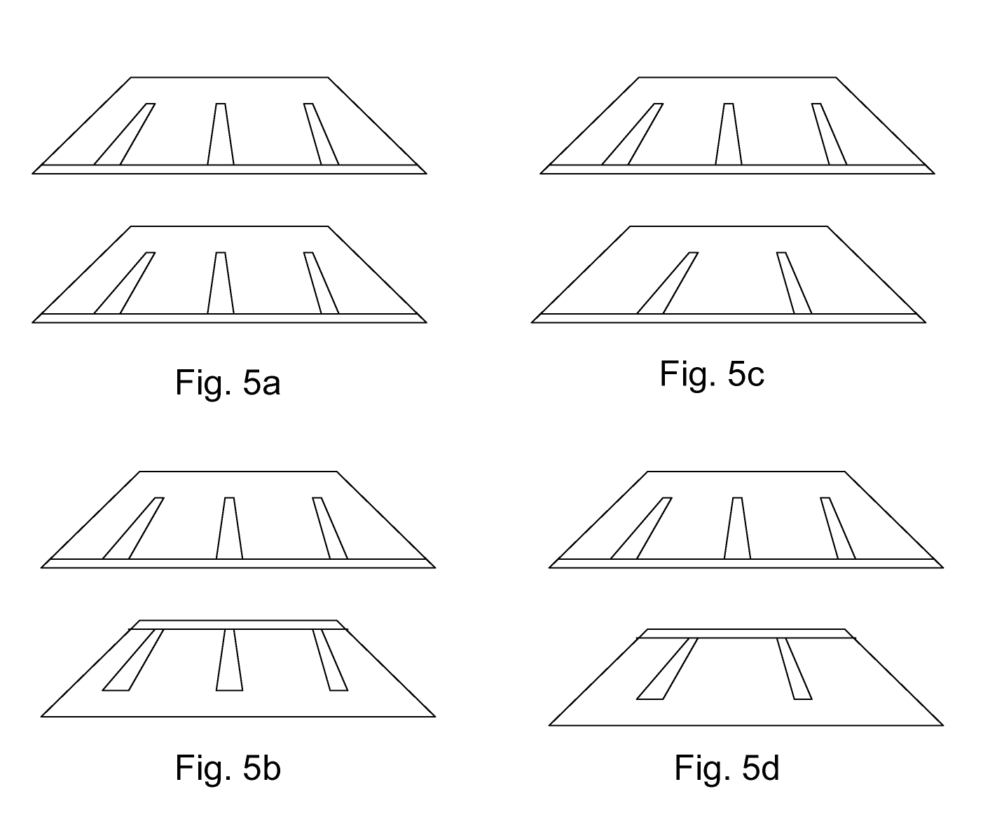

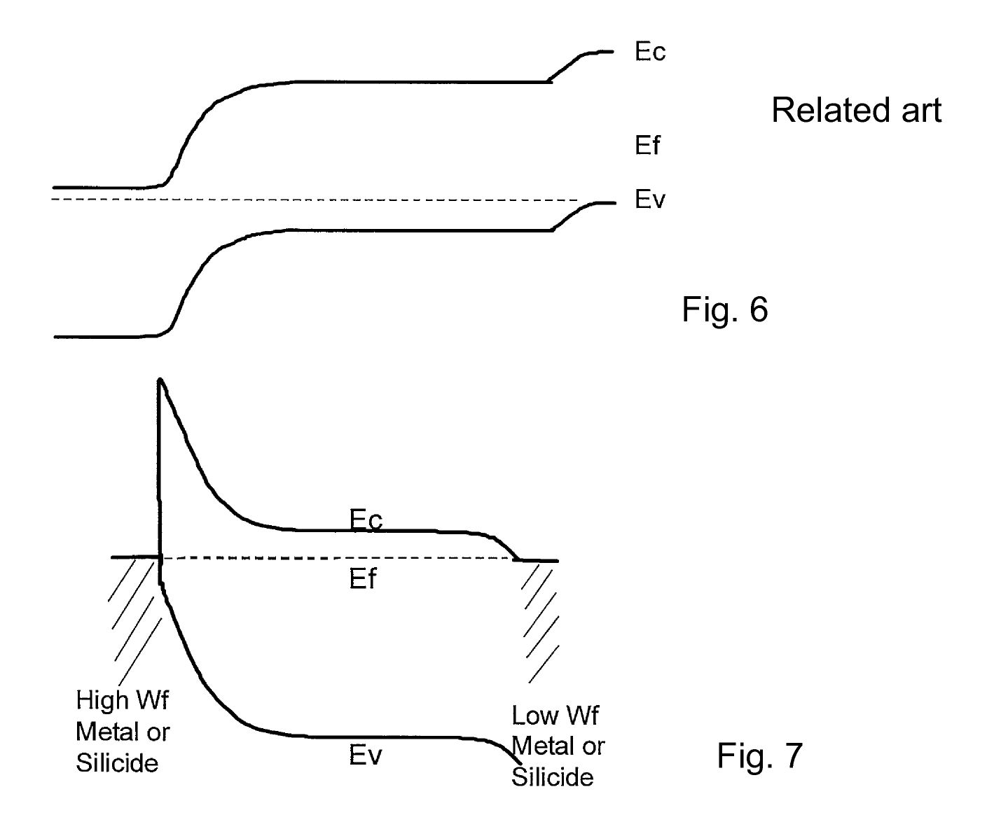

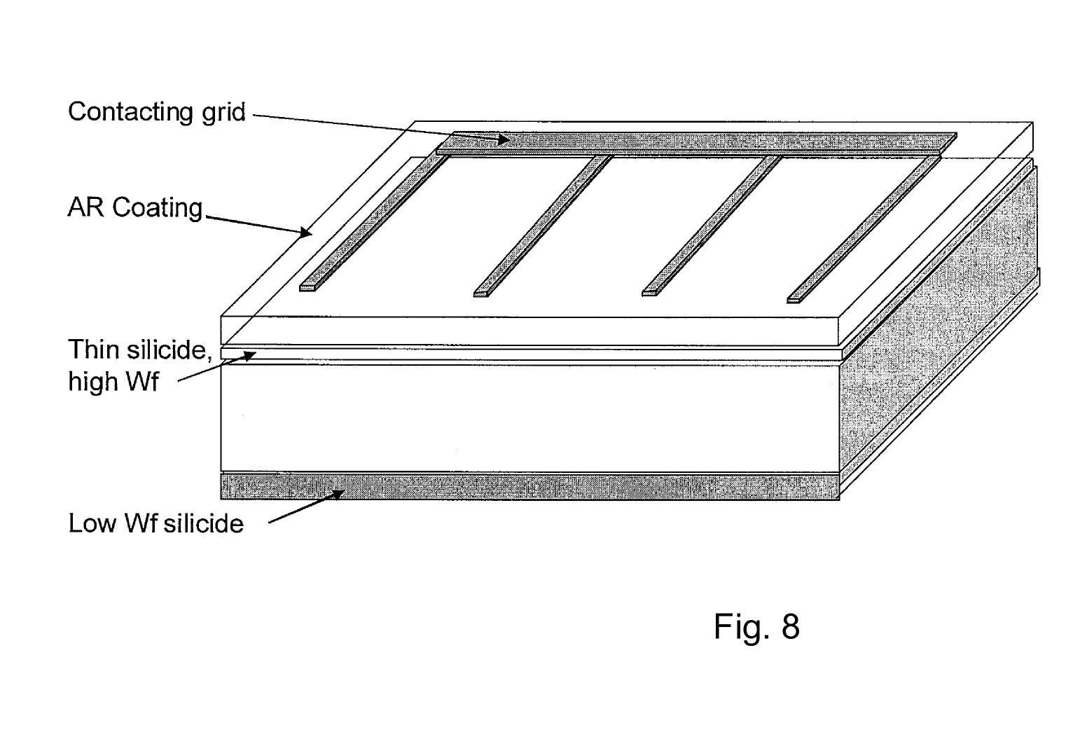

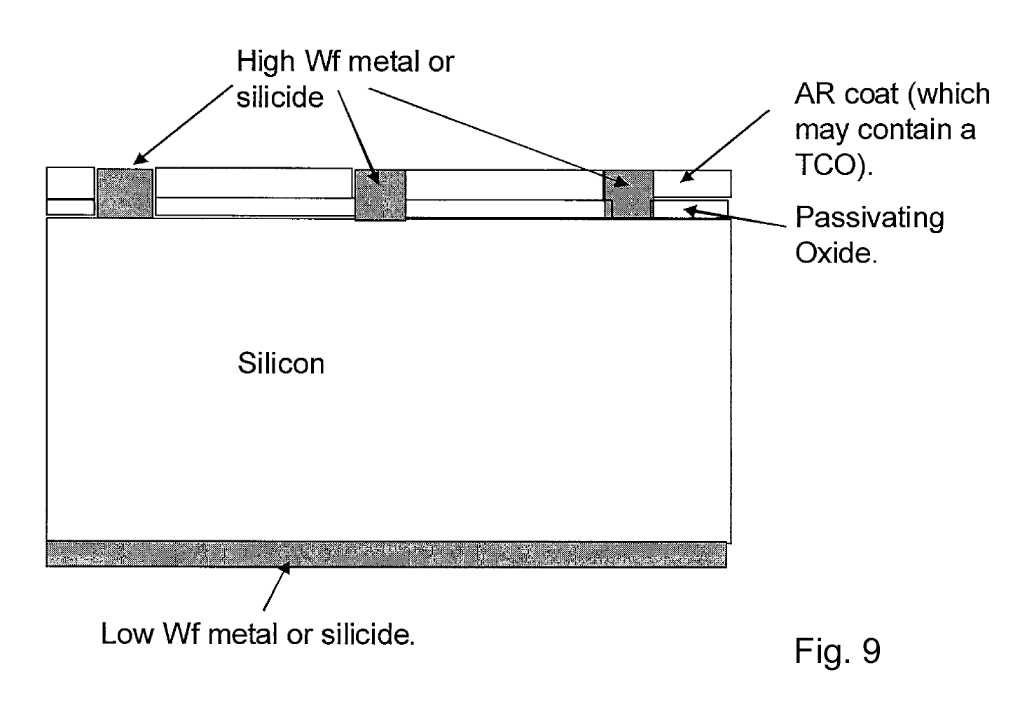

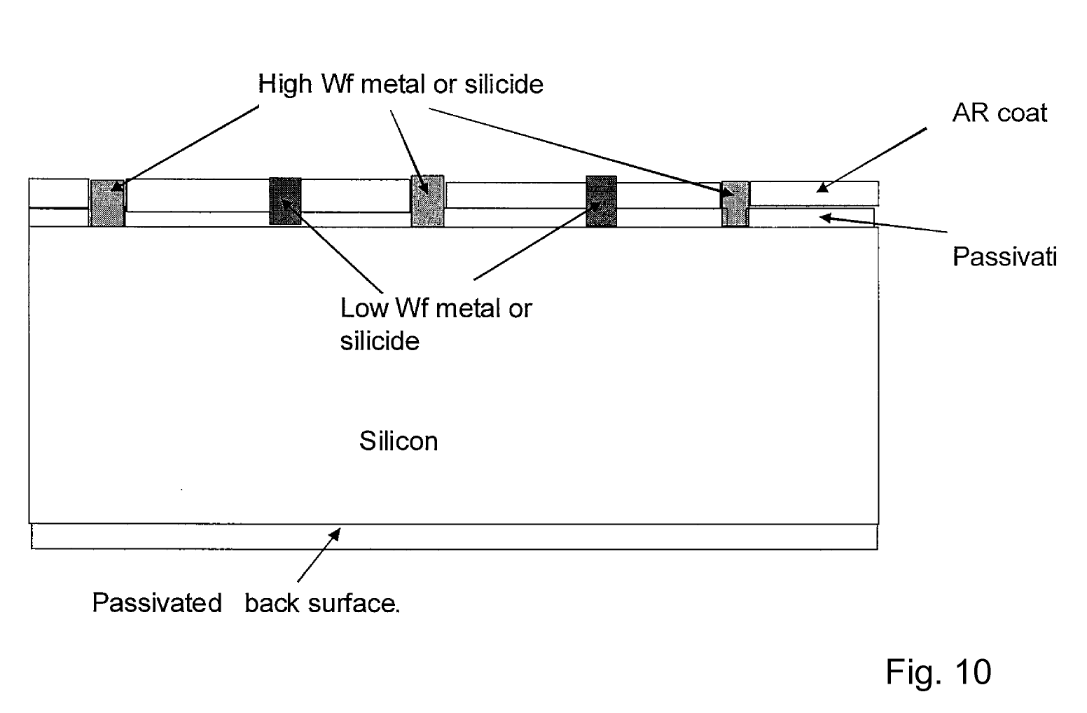

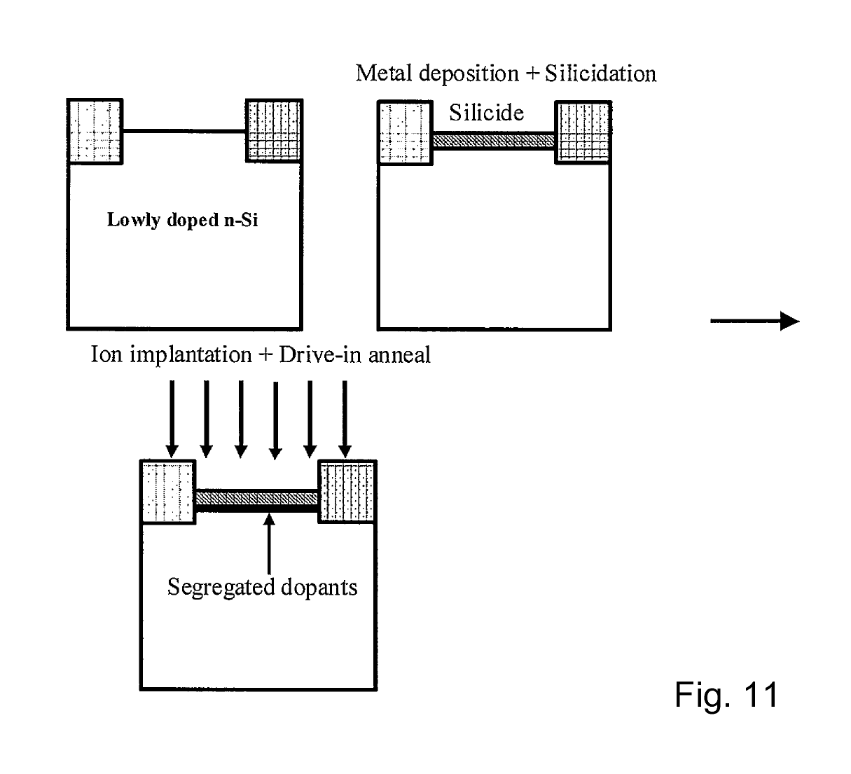

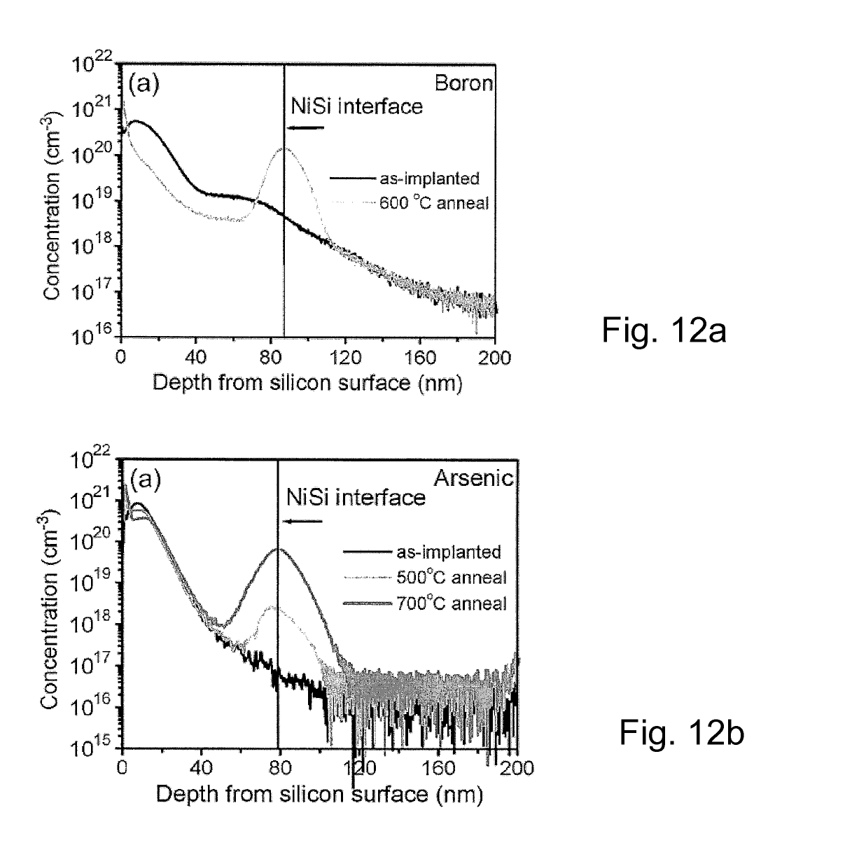

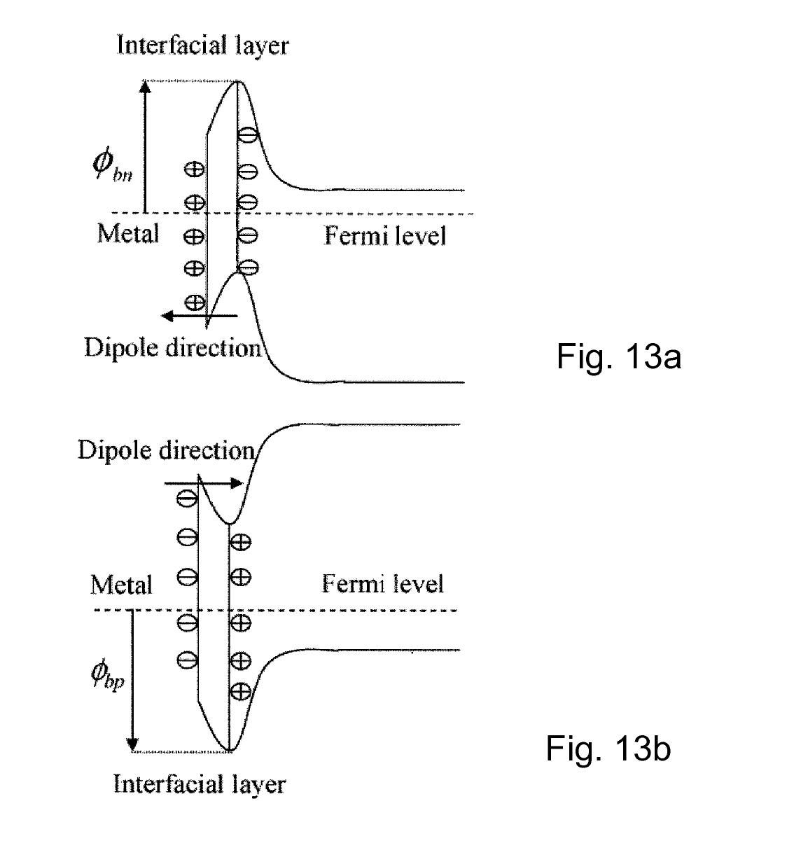

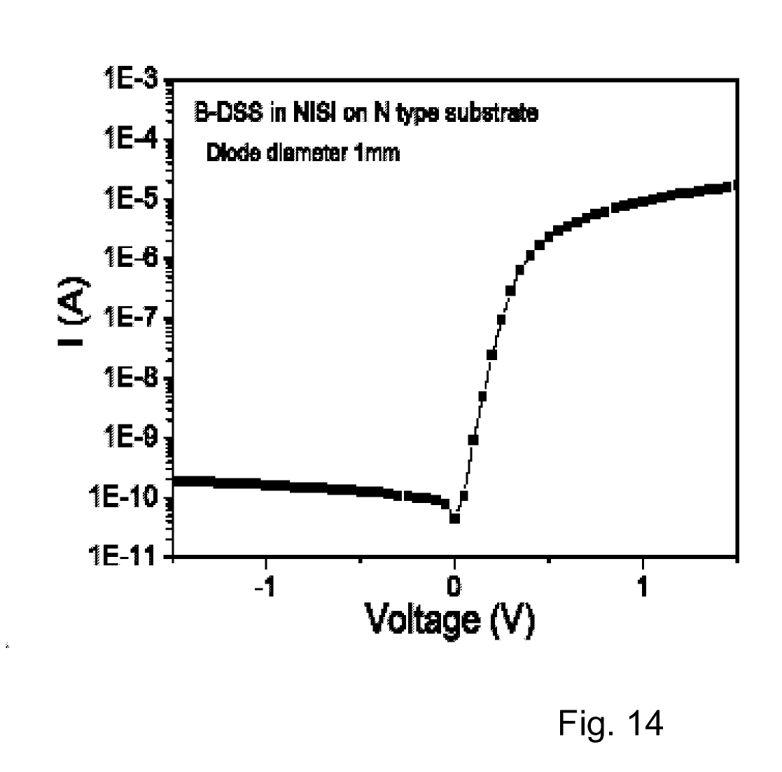

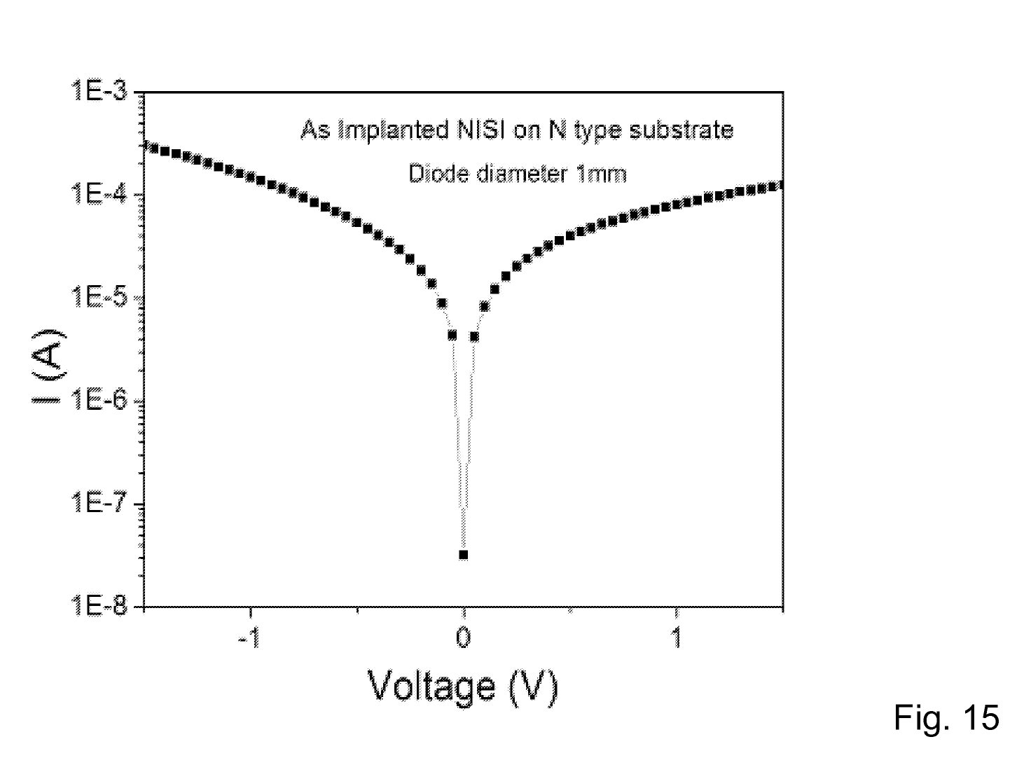

FIG. 1b shows a top view of a Schottky barrier solar cell wherein a high or a low work function region 150 is provided on the front surface. Electrons are collected through collector 140 made from a conductive material.

FIGS. 2a to 2f show various geometries contemplated in this disclosure for the arrangement of p-doped, n-doped, high work function, and low work function regions, respectively.

FIG. 2a shows high work function region 210 being provided on a partial area of the front surface of the lightly doped absorber and low work function region 220 being provided on the back surface of the lightly-doped absorber.

FIG. 2b shows low work function region 220 being provided on a partial area of the front surface of the lightly doped absorber and high work function region 210 being provided on the back surface of the lightly-doped absorber.

FIG. 2c shows p-doped region 230 being provided on a partial area of the front surface of the lightly doped absorber and a low work function region 220 being provided on the back surface of the lightly doped absorber.

FIG. 2d shows low work function region 220 being provided on a partial area of the front surface of the lightly doped absorber and p-doped region 230 being provided on the back surface of the lightly doped absorber.

FIG. 2e shows n-doped region 240 being provided on a partial area of the front surface of the lightly doped absorber and high work function region 210 being provided on the back surface of the lightly doped absorber.

FIG. 2f shows high work function region 210 being provided on a partial area of the front surface of the lightly doped absorber and n-doped region 240 being provided on the back surface of the lightly doped absorber.

FIGS. 3a to 3e show various geometries contemplated in this disclosure for the partial arrangement of p-doped, n-doped, high work function, and low work function regions on the front and/or back surface of the lightly doped absorber.

FIG. 3a shows high work function region 210 being provided on a partial area of the front surface of the lightly doped absorber and low work function region 220 being provided on a partial area of the back surface of the lightly doped absorber.

FIG. 3b shows high work function region 210 being provided on a partial area of the front surface of the lightly doped absorber and low work function region 220 being provided on a separate partial area of the front surface of the lightly doped absorber.

FIG. 3c shows high work function region 210 being provided on a partial area of the back surface of the lightly doped absorber and low work function region 220 being provided on a separate partial area of the back surface of the lightly doped absorber.

FIG. 3d shows p-doped region 230 being provided on a partial area of the front surface of the lightly doped absorber and low work function region 220 being provided on a separate partial area of the front surface of the lightly doped absorber.

FIG. 3e shows high work function region 210 being provided on a partial area of the back surface of the lightly doped absorber and n-doped region 240 being provided on a separate partial area of the back surface of the lightly doped absorber.

FIGS. 4a, 4b, and 4c show the embodiments of FIGS. 2a, 2c, and 2d, respectively, which additionally contain a supplemental, at-least-partially-transparent, potential-difference-inducing layer 410. Layer 410 may be a doped Si layer, a doped semiconductor layer, or a high-or-low work function metal-containing layer. If layer 410 is a doped Si layer, it is doped with a dopant having the opposite charge than the dopant of the lightly doped absorber. Further, if layer 410 is a high-or-low work function metal-containing layer and the lightly-doped absorber is p-doped, layer 410 is a low work function metal-containing layer. Conversely, if layer 410 is a high-or-low work function metal-containing layer and the lightly-doped absorber is n-doped, layer 410 is a high work function metal-containing layer.

FIG. 4d shows upper the front surface of a Schottky barrier cell wherein high work function region 210 is provided on a partial area of the front surface in the form of digits and is connected to collector 140.

FIG. 4e shows alternate high work function regions 210 and low work function regions 220 located on the same side of absorber region 100 and connected to collectors 140 and 145, respectively.

FIGS. 5a-5d show various geometries in which n-/p-doped regions and/or high/low work function regions may be arranged on the front and back surface of lightly-doped absorber 100.

FIG. 6 shows a band diagram of a related art N+/P/P+ solar cell.

FIG. 7. shows a band diagram of a Schottky barrier solar cell having two potential barrier junctions based on the provision of a high work function region and a low work function region.

FIG. 8 shows an operational Schottky barrier solar cell with an anti-reflective (AR) coating and a contacting grid for efficiently collecting electrons.

FIG. 9 shows a side view of the operational Schottky barrier cell of FIG. 8.

FIG. 10 shows an operational Schottky barrier solar cell in which high work function regions and low work function regions are provided, spatially apart and interdigitated, on the front surface of a lightly doped absorber.

FIG. 11 shows a schematic process flow for the preparation of a high or low work function region on a surface of lightly doped n-Si.

FIG. 12a shows the depth profile of the concentration of a boron doped NiSi interface as implanted and after a 600° C. anneal.

FIG. 12b shows the depth profile of the concentration of an arsenic doped NiSi interface as implanted, after a 500° C. anneal, and after a 700° C. anneal.

FIG. 13a shows the band diagram of Schottky barrier at a NiSi/nSi interface obtained via interface modification via dopant segregation.

FIG. 13b shows the band diagram of a Schottky barrier at a NiSi/pSi interface obtained by interface modification via dopant segregation.

FIG. 14 shows a current-voltage curve of a Schottky diode comprising a high work function metal silicide on n-type Si.

FIG. 15 shows a current-voltage curve of a Schottky diode comprising a low work function metal silicide on n-type Si.

### DESCRIPTION OF THE BEST AND VARIOUS EMBODIMENTS

The foregoing and other objects, aspects and advantages will be better understood from the following detailed description of the best and various embodiments. Throughout the various views and illustrative embodiments of the present disclosure, like reference numbers are used to designate like elements.

In a typical embodiment, a Schottky barrier solar cell is obtained by placing a metallic material with a high work function onto a part of a lightly-doped absorber and placing a second metallic material in a different location using a low work function metallic material. The high work function region and low work function region are also referred to herein as contacts. Typically, a low temperature annealing of the metallic materials is performed to form silicides if the substrate material is Si, to form gemanides if the substrate material is Ge, or to form the corresponding metal-containing regions on alternate substrates, such as GaAs. However, high and low work function silicides and germanides may also be deposited directly (e.g., by sputtering from a compound target). Placing both metallic materials as a high work function region and a low work function region on the front surface of a lightly doped absorber creates an interdigitated front contact device (IFC), but alternatively one of the metallic materials, typically the Schottky barrier forming metal, is placed on the front surface and the opposite metal on the absorber back surface. The metallic materials may be thin to be semi-transparent or thick if transparency is not required. The surface of the space between contacts is passivated and the pitch (distance between contacts) is determined by the typical diffusion length of the substrate material.

Alternatively, a silicide of the same metal can be used to form both the high and low work function junctions by incorporating p-type or n type dopants to tailor the local work function, producing high barrier height Schottky junctions and low barrier height ohmic contacts. The same flexibility as described above is still applicable: the device can be made in IFC form or with the metal junctions on alternate sides Annealing is used to create the silicides and to activate the desired dopants incorporated into the silicide or into the Si adjacent to the silicide.

Typically, the lightly doped absorber is monocrystalline or polycrystalline. With particularity, the lightly doped absorber is selected from the group consisting of Si, Ge, and SiGe alloys.

In a typical embodiment, the at least one of the high work function region or the low high work function region is selected from the group consisting of metal, metal silicide, metal germanide, or mixtures or multilayers thereof. With particularity, the metal is selected from the group consisting of nickel, platinum, nickel platinum, cobalt, titanium, and tungsten.

In another typical embodiment, the at least one of the high work function region or the low high work function region further comprises a dopant that is distributed within the metal-containing material and/or at an interface with the lightly-doped absorber and is selected from the group consisting of aluminum, arsenic, boron, gallium, indium, phosphorous, and antimony.

With particularity, the Schottky barrier solar cell comprises blanket or patterned conductive contact layer on at least part of the front surface or the back surface. Also with particularity, the at least one p-doped region or high work function region is disposed on the front surface of the absorber layer and the at least one n-doped region or low work function region is disposed on the back surface of the absorber layer, or the at least one p-doped region or high work function region is disposed on the back surface of the absorber layer and the at least one n-doped region or low work function region is disposed on the front surface of the absorber layer.

Typically, the at least one p-doped region or high work function region and the at least one n-doped region or low work function region are laterally spaced apart in an interdigitated pattern on a same surface of the lightly doped absorber. The same surface may be either the front surface or the back surface.

Also typically, the Schottky barrier solar cell comprises a supplemental doped layer on the same surface, wherein the supplemental doped layer has a same dopant as the lightly doped absorber, and wherein a concentration of the same dopant is greater in the supplemental doped layer than in the lightly doped absorber.

In another typical embodiment, the high work function region and the low work function region include a same metal, each modified, for example, by dopant-engineering, to have the appropriate work function. With particularity, the Schottky barrier solar cell further comprises a conductive contact, a transparent conductive oxide layer, an antireflective coating, a surface texture, and a surface passivation layer.

In a typical embodiment the lightly-doped absorber is n-doped. In yet another typical embodiment the lightly-doped absorber is p-doped.

Typically, a concentration of a dopant in the lightly-doped absorber is of from about 1·10¹³ atoms cm⁻³ to about 1·10¹⁷ atoms cm⁻³. Also typically, a concentration of the same dopant in the supplemental absorber region is of from about 1·10¹⁷ atoms cm⁻³ to about 1·10²¹ atoms cm⁻³.

With particularity, a concentration of a dopant in the p-doped region is of from about 1·10¹³ atoms cm⁻³ to about 1·10¹⁷ atoms cm⁻³. Also with particularity, a concentration of a dopant in the n-doped region is of from about 1·10¹⁷ atoms cm⁻³ to about 1·10²¹ atoms cm⁻³.

Another embodiment method of forming a Schottky barrier solar cell comprises: forming at least one of a p-doped region and a high work function region on the lightly-doped absorber, forming at least one of a n-doped region and a low work function region abutting the lightly-doped absorber and being spaced apart from the at least one of p-doped region or high work function region, wherein the Schottky barrier solar cell comprises at least one of the high work function region or the low high work function region; and adjusting a potential difference at an interface between the high work function region with the lightly-doped absorber or the low high work function region and the lightly-doped absorber to be at least 0.2 volts.

Yet another embodiment of forming a Schottky barrier solar cell comprises: providing a lightly-doped absorber having a front surface and a back surface; forming a p-doped region and an n-doped region on the lightly-doped absorber; converting at least one of the p-doped region and the n-doped region into a metal silicide film.

A Schottky barrier solar cell of metallic materials with high work functions (Wfs) and low work functions contains two built-in potential differences. Such a structure is shown in FIG. 7 for n-type substrates. The total built-in potential is the sum of the two barrier potentials and can be comparable to the p/n junction built-in potential of FIG. 6. In an exemplary embodiment, platinum or iridium are used for the high Wf metallic material and Yb or Er for the low Wf metallic material.

For Schottky barrier solar cells possessing silicided contacts, a TiN cap can be deposited on top of the low Wf and high Wf metals to prevent oxidation of the metals before forming the silicide. The annealing conditions for both types of silicides are in the range of 400° C. to 600° C., with the preferred embodiment being 500° C., 30 seconds for Er silicide and 420° C., 30 seconds for Pt silicide. The TiN cap and unreacted metal are then stripped from the structure using a wet etch, such as sulfuric acid/hydrogen peroxide for Er and Aqua regia for Pt.

When two silicides are used, it is preferred to protect the first silicide formed from the cleaning and selective stripping processes performed in the forming of the second silicide. A conductive TiN cap layer can be used to protect the first silicide formed (e.g., Er silicide) from attack by HF used to clean the lightly doped absorber surface on which the second silicide (or metal) is formed. Additional layers may be used as needed.

FIG. 8 shows one embodiment where the surface is a blanket metal or metal silicide with a thickness of 15 nm or less, covered with an anti-reflective (AR) coating and a metal contacting grid. In this embodiment, one Schottky junction is present on the front surface and one Schottky junction on the back surface.

FIG. 9 shows another embodiment using an IFC (Interdigitated Front Contact) approach for the front while retaining the low Wf silicide on the back. The free Si surface in the space between contacts is passivated using, for example, thermal SiO₂, that is 7 nm or more in thickness, and an antireflective (AR) coat covers the passivated surface as well. a transparent conducting oxide (TCO), such as SnO₂, ZnO₂, In₂O₃ or the like, and can form part of the AR coating and contributes to conducting current in parallel with the metal silicide contact fingers. In this embodiment, the high Wf silicide on the front surface does not need to be thin.

FIG. 10 shows another embodiment in which both the high and low Wf metals are on the front surface, forming an alternating interdigitated high Wf , low Wf set of contacts. Neither metal silicide needs to be thin, and AR coatings are also used. While a TCO can optionally be incorporated, it would require patterning to prevent short circuiting the two alternate contacts. The back surface is passivated to prevent losses in performance due to surface recombination.

The interdigitated device of FIG. 10 is shown with both high and low Wf metals or metal silicides on the front (light receiving) surface but alternately both contacts could be on the back surface opposite the light-receiving surface of the lightly doped absorber, making it an IBC (Interdigitated Back Contact) device.

For the digitated and interdigitated devices of FIGS. 9 and 10, the spacing (“pitch”) between the fingers is preferably less than or equal to about two minority carrier diffusion lengths in the substrate material. The concept works for both thick and thin film Si as long as that criteria is retained. The device of FIG. 10 can also be used with Si films on insulating substrates.

While the examples of the present disclosure utilize Schottky barriers of metals with high work functions and low work functions to create the two potential differences, solar cells in which one potential difference is created by a Schottky barrier and a second potential difference is created by conventional doping (diffusion, ion implantation, or in-situ doping during semiconductor layer growth) are also contemplated.

In another embodiment, the same metal can be used for both silicides by adding acceptor or donor dopants into the silicide and adjacent regions of the Si . Both high Wf and low Wf can be achieved from one silicide by interface modification. A very promising way to modify the silicide /Si interface is dopant-segregation as illustrated in Fig . 11.

First, a lightly doped substrate is isolated with Field Oxide (FOX) to form active junction areas (FIG. 11a). A metal or metal mixture, for example Ni or Ni—Pt, is then deposited on the wafer followed by self -aligned silicide process to form silicide/Si Schottky junctions (FIG. 11b). Dopants, such as B or As, are first implanted into the thus formed silicide layer to form high Wf and low Wf regions, respectively. The implantation energy is preferably kept at a lever where the silicide-Si interface is not damaged and no interface states are introduced by the implantation. A subsequent drive-in anneal at temperature less than 700° C. causes the dopants to diffuse towards the silicide-Si interface, as demonstrated in FIGS. 11C and 12a and 12b. First-principles calculations suggest that the system assumes its most stable state when B atoms occupy the substitutional sites within the first Si monolayers in the close vicinity of the silicide/silicon interface. As a result, these substitutional B atoms are charged by the interface states, forming electric dipoles across the interface. FIGS. 13a and 13b schematically illustrate how the deformation of the energy band is induced by the dipoles. Based on the experimental results, substitutional B atom are expected to be negatively charged and to bend energy band upwards leading to an increased electron Schottky Barrier Height (SBH) from silicide to Si (FIG. 13(a)), while substitutional As and P atoms are positively charged and therefore bend energy band downwards leading to an increased hole SBH (FIG. 13(b)).

In a preferred embodiment, Ni is used as the metal for the metal silicide because the self-aligned Ni silicide process is well-understood and considered a mature processing method. Ni is the dominating diffusion species during the silicide reaction and NiSi has very low resistivity (about 10 μΩ·cm). The dopant-segregation can also be induced by implantation into Si, which is then followed by silicidation or by implantation into metal, which is then followed by silicidation. To further reduce processing costs, sputter pre-doped metal targets (Ni—B or Ni—As) or electrolessly plated Ni—B or Ni—As are considered to be other promising manufacturing routes.

The embodiments described hereinabove are further intended to explain best modes known of practicing it and to enable others skilled in the art to utilize the disclosure in such, or other, embodiments and with the various modifications required by the particular applications or uses. Accordingly, the description is not intended to limit it to the form disclosed herein. Also, it is intended that the appended claims be construed to include alternative embodiments.

The foregoing description of the disclosure illustrates and describes the present disclosure. Additionally, the disclosure shows and describes only the preferred embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The term “comprising” (and its grammatical variations) as used herein is used in the inclusive sense of “having” or “including” and not in the exclusive sense of “consisting only of” The terms “a” and “the” as used herein are understood to encompass the plural as well as the singular.

All publications, patents and patent applications cited in this specification are herein incorporated by reference, and for any and all purpose, as if each individual publication, patent or patent application were specifically and individually indicated to be incorporated by reference. In the case of inconsistencies, the present disclosure will prevail.

What is claimed is:

1. A Schottky barrier solar cell comprising
a lightly-doped absorber having a front surface and a back surface;
at least one of a p-doped region and a high work function region disposed on the lightly-doped absorber; and
at least one of a n-doped region and a low work function region abutting the lightly-doped absorber and being spaced apart from the at least one of p-doped region or high work function region;
wherein the Schottky barrier solar cell comprises at least one of the high work function region or the low high work function region.

2. The Schottky barrier cell according to claim 1, wherein the lightly doped absorber is monocrystalline or polycrystalline.

3. The Schottky barrier cell according to claim 1, wherein the lightly doped absorber is selected from the group consisting of Si, Ge, and SiGe alloys.

4. The Schottky barrier cell according to claim 1, wherein at least one of the high work function region or the low high work function region is selected from the group consisting of metal, metal silicide, metal germanide, or mixtures or multilayers thereof

5. The Schottky barrier cell according to claim 4, wherein the metal is selected from the group consisting of nickel, palladium, platinum, cobalt, titanium, tungsten, Er, Yb or an alloy of two or more of these metals.

6. The Schottky barrier cell according to claim 1, wherein the at least one of the high work function region or the low high work function region comprises a dopant that is distributed within the at least one of the high work function region or the low high work function region and/or at an interface of the at least one of the high work function region or the low high work function region with the lightly-doped absorber, and
wherein the dopant is selected from the group consisting of aluminum, arsenic, boron, gallium, indium, phosphorous, antimony, sulfur, selenium and fluorine.

7. The Schottky barrier solar cell according to claim 1, further comprising a blanket or patterned conductive contact layer on at least a part of the front surface or of the back surface.

8. The Schottky barrier solar cell according to claim 1, wherein the at least one p-doped region or high work function region is disposed on the front surface of the absorber layer and the at least one n-doped region or low work function region is disposed on the back surface of the lightly-doped absorber, or wherein the at least one p-doped region or high work function region is disposed on the back surface of the absorber layer and the at least one n-doped region or low work function region is disposed on the front surface of the lightly-doped absorber.

9. The Schottky barrier solar cell according to claim 1, wherein the at least one p-doped region or high work function region and the at least one n-doped region or low work function region are laterally spaced apart in an interdigitated pattern on a same surface of the lightly doped absorber.

10. The Schottky barrier solar cell according to claim 9, wherein the same surface is the front surface.

11. The Schottky barrier solar cell according to claim 9, further comprising a supplemental doped layer on the same surface, wherein the supplemental doped layer has a same dopant as the lightly doped absorber, and wherein a concentration of the same dopant is greater in the supplemental doped layer than in the lightly doped absorber.

12. The Schottky barrier solar cell according to claim 8, comprising the high work function region and the low work function region, wherein the high work function region and the low work function region include a same metal.

13. The Schottky barrier solar cell according to claim 1, further comprising at least one of a conductive contact, a transparent conductive oxide layer, an antireflective coating, a surface texture, and a surface passivation layer.

14. The Schottky barrier solar cell according to claim 1, wherein the lightly-doped absorber is p-doped.

15. The Schottky barrier solar cell according to claim 1, wherein the lightly-doped absorber is n-doped.

16. The Schottky barrier solar cell according to claim 1, wherein a concentration of a dopant in the lightly-doped absorber is of from about 1·10¹³ atoms cm⁻³ to about 1·10¹⁷ atoms cm⁻³.

17. The Schottky barrier solar cell according to claim 11, wherein a concentration of the same dopant in the supplemental absorber region is of from about 1·10¹⁷ atoms cm⁻³ to about 1·10²¹ atoms cm⁻³.

18. The Schottky barrier solar cell according to claim 1, wherein a concentration of a dopant in the p-doped region is of from about 1·10¹³ atoms cm⁻³ to about 1·10¹⁷ atoms cm⁻³.

19. The Schottky barrier solar cell according to claim 1, wherein a concentration of a dopant in the n-doped region is of from about 1·10¹⁷ atoms cm⁻³ to about 1·10²¹ atoms cm⁻³.

20. A method of forming a Schottky barrier solar cell, comprising:
providing a lightly-doped absorber having a front surface and a back surface;
forming at least one of a p-doped region and a high work function region on the lightly-doped absorber; and
forming at least one of a n-doped region and a low work function region abutting the lightly-doped absorber and being spaced apart from the at least one of p-doped region or high work function region;
wherein the Schottky barrier solar cell comprises at least one of the high work function region or the low high work function region; and
adjusting a potential difference at an interface between the high work function region with the lightly-doped absorber or the low high work function region and the lightly-doped absorber to be at least 0.2 volts.

21. The Schottky barrier solar cell according to claim 9, wherein the same surface is the front surface and wherein the front surface is a light-receiving surface.

22. The Schottky barrier solar cell according to claim 9, wherein the same surface is the back surface and wherein the front surface is a light-receiving surface.
